(19) United States
(12) Patent Application Publication
(10) Pub. No.: US 2024/0337696 A1
(43) Pub. Date: Oct. 10, 2024

(54) RESIDUAL STATE OF CHARGE RUNTIME UPDATE

(71) Applicant: TEXAS INSTRUMENTS INCORPORATED, Dallas, TX (US)

(72) Inventors: Yicheng Zhou, Shanghai (CN); Xiaodong Li, Shanghai (CN); Yuhao Zhao, Shanghai (CN)

(21) Appl. No.: 18/362,243

(22) Filed: Jul. 31, 2023

Related U.S. Application Data
(60) Provisional application No. 63/458,265, filed on Apr. 10, 2023.

(51) Int. Cl. G01R 31/367; G01R 31/388

(52) U.S. Cl. CPC G01R 31/367; G01R 31/388

(57) ABSTRACT

A method comprises recording a first voltage value of a voltage source, recording a second voltage value of the voltage source, and determining a first estimated residual state of charge value (SOC_{estimated}) of the voltage source based on the first voltage value and the second voltage value. The method also comprises determining a factor based on one of the first voltage value and the second voltage value and calculating a residual state of charge value (SOC_{residual}) of the voltage source based on the first estimated residual state of charge value (SOC_{estimated}) and based on the factor.

### CROSS-REFERENCE TO RELATED APPLICATIONS

This application claims the benefit to and priority of U.S. Provisional Application No. 63/458,265, filed Apr. 10, 2023. The entire disclosure of the above application is incorporated herein by reference.

### TECHNICAL FIELD

Aspects of the disclosure are related to apparatus and systems incorporating direct current (DC) voltage sources and, in particular, to determining battery state of charge.

### BACKGROUND

The state of charge (SOC) of a battery is an important characteristic in a battery management system (BMS). However, the full charge capacity (FCC) of the battery is affected by current, temperature, and life cycles.

A first approach to determining the residual SOC uses a predicted end discharge voltage (EDV) threshold based on minimum and maximum load constraints and temperature variations. This approach may experience increased errors after large life cycles and may lose capacity at low discharge. In addition, this approach needs one or more learning cycles to learn the capacity using a coulometer.

A second approach uses a dynamic threshold based on tracked impedance learning. This approach has a complex battery chemical generation and input and needs one or more learning cycles to learn the capacity using a coulometer.

It would be beneficial to have an approach that determines residual SOC at different temperatures and for different loads that reduces or eliminates the use of learning cycles.

### SUMMARY

In accordance with one aspect of the present disclosure, a method comprises recording a first voltage value of a voltage source, recording a second voltage value of the voltage source, and determining a first estimated residual state of charge value (SOC_{estimated}) of the voltage source based on the first voltage value and the second voltage value. The method also comprises determining a factor based on one of the first voltage value and the second voltage value and calculating a residual state of charge value (SOC_{residual}) of the voltage source based on the first estimated residual state of charge value (SOC_{estimated}) and based on the factor.

In accordance with another aspect of the present disclosure, an apparatus comprises a controller configured to receive a first voltage measurement value of a DC voltage source from a voltage sensor, receive a second voltage measurement value of the DC voltage source from the voltage sensor, and calculate an estimated residual state of charge value (SOC_{estimated}) based on the first and second voltage measurement values. The controller is further configured to calculate a modification factor (Factor) and calculate a residual state of charge (SOC_{residual}) of the DC voltage source based on the estimated residual state of charge value (SOC_{estimated}) and on the modification factor (Factor).

In accordance with another aspect of the present disclosure, an apparatus comprises one or more computer readable storage media and program instructions stored on the one or more computer readable storage media, the program instructions executable by a processing system to direct the processing system to receive a voltage measurement and a subsequent voltage measurement of a voltage source and estimate a residual state of charge value (SOC_{estimated}) based on the voltage measurement and the subsequent voltage measurement. The program instructions also direct the processing system to determine a factor and determine a residual state of charge (SOC_{residual}) of the voltage source based on the estimated residual state of charge value and based on the factor.

### BRIEF DESCRIPTION OF THE DRAWINGS

Many aspects of the disclosure may be better understood with reference to the following drawings. The components in the drawings are not necessarily to scale, emphasis instead being placed upon clearly illustrating the principles of the present disclosure. Moreover, in the drawings, like reference numerals designate corresponding parts throughout the several views. While several embodiments are described in connection with these drawings, the disclosure is not limited to the embodiments disclosed herein. On the contrary, the intent is to cover all alternatives, modification's, and equivalents.

FIG. 1 is a schematic block diagram of a system incorporating a DC voltage source in an implementation.

FIG. 2 illustrates exemplary waveforms of battery voltage discharge in an implementation.

FIG. 3 is a schematic block diagram illustrating a method for determining battery state of charge in an implementation.

FIG. 4 is a flowchart illustrating a method for determining battery residual state of charge in an implementation.

FIG. 5 illustrates a voltage plot and calculation of a residual state of charge using voltage measurements in an implementation.

FIG. 6 illustrates a plot for determining a factor based on measured voltages in an implementation.

FIG. 7 is a block diagram illustrating modification of a determined battery residual state of charge in an implementation.

FIG. 8 illustrates a lookup table mapping example of the temperature-current table of FIG. 7 in an implementation.

FIG. 9 illustrates a computing system suitable for implementing the various operational environments, architectures, processes, scenarios, and sequences discussed below with respect to the other Figures.

### DETAILED DESCRIPTION

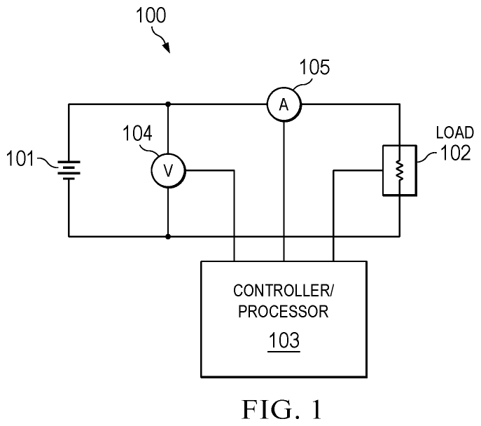

Systems, methods, and devices are disclosed herein related to parameters of battery state of charge (SOC) to improve determining the SOC for increased accuracy in reporting SOC to a user, for example, or for optimizing battery use including energy draw and charging in a system incorporating battery power. In one example, FIG. 1 illustrates a schematic block diagram of a battery powered system 100 incorporating a direct current (DC) voltage source in an implementation. A voltage source 101 such as a battery is included in the system 100 and provides some or all of the power to a load 102. A controller 103 or other control device, such as a processor, may be coupled to the load 102 for controlling various operations of the load 102 that can be influenced by the SOC of the voltage source 101. A voltage meter 104 and a current meter 105 connected to the voltage source 101 provide voltage and current measurements to the controller 103 for determining the SOC based on, for example, a measured voltage stored in the voltage source 101 and an amount of current draw demanded or used by the load 102.

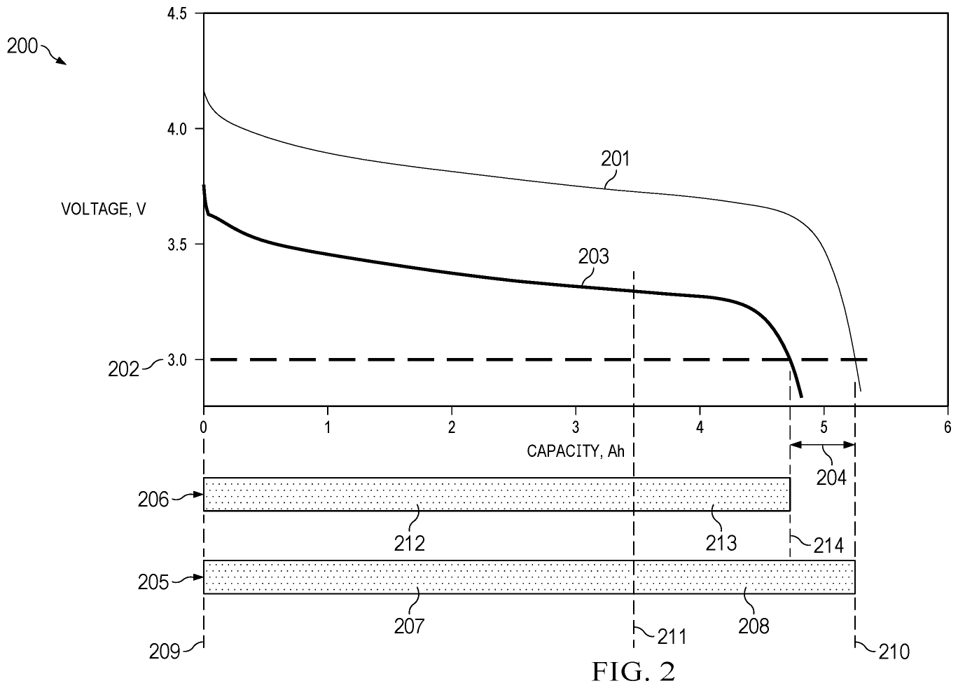

FIG. 2 illustrates exemplary waveforms of battery voltage discharge in an implementation. A voltage discharge plot 200 shows an example open circuit voltage (OCV) discharge waveform 201 according to a first example of energy draw from a battery such as the battery 101 of FIG. 1. As the amp-hour (Ah) energy stored in the battery gets used (e.g., from 0 Ah toward 6 Ah), the OCV continuously drops as indicated by the voltage discharge waveform 201, but the rate of OCV drop varies as shown by the changes in slope of the various portions of the voltage discharge waveform 201. Near the end of the usable energy able to be supplied by the battery, an increase in the loss of OCV occurs to dramatically take the OCV to an “empty level” 202 at a much faster rate than during a majority of the previous OCV loss. The empty level indicates the level at which the full chemical capacity (Qₘₐₓ) of the battery is spent. In the illustrated example, the empty level 202 is 3 volts; however, the empty level 202 is dependent on conditions such as battery chemistry, temperature, age, life cycle, current draw, and other parameters and can be different for batteries of different sizes, capacities, chemistries, and the like.

Under an ideal scenario in which the usable capacity of the battery remained the same regardless of the external and internal conditions experienced by or demanded of the battery, determining the SOC for purposes of displaying remaining battery capacity to a user or for controlling operations of the load 102 based on the remaining SOC could be based on the capacity used so far compared with the never changing total usable capacity (e.g., the Ah value of the empty level 202). However, the total usable capacity is not a fixed ideal value and can be influenced by similar conditions described above such as temperature, age, life cycle, current draw, and other parameters. A second waveform 203 illustrated in FIG. 2 illustrates the circuit voltage of the same battery under different use conditions such as at a different temperature and at an increased current draw. Based on the effects caused by such conditions, the circuit voltage is lower across the usable chemical capacity of the battery, and the voltage discharge waveform 203 terminates at the empty level 202 at a lower Ah rating than the voltage discharge waveform 201. A difference between the Ah values of the voltage discharge waveform 201 discharging to the empty level 202 and the empty level 202 discharging to the empty level 202 is referred to herein as the residual SOC 204.

FIG. 2 further illustrates a pair of indicators 205, 206 showing SOC capacity of the battery based on the voltage discharge waveforms 201, 203. The first capacity indicator 205 includes a used capacity portion 207 and a remaining capacity portion 208. The indicator 205 extends from a full charge capacity level 209 (0 Ah) to an empty discharge capacity level 210 (approx. 5.2 Ah). An SOC of the battery at an SOC point 211 is determinable by calculating a percentage of the remaining capacity portion 208 to the full capacity available (e.g., the used capacity portion 207 and the remaining capacity portion 208). In an example where the SOC point 211 is at a capacity level of 3.4 Ah, the SOC value may be calculated as (5.2-3.4)/5.2=34.6% SOC. The indicator 206 includes a used capacity portion 212 and a remaining capacity portion 213 and extends from the full charge capacity level 209 (0 Ah) to an empty charge capacity level 214 (approx. 4.8 Ah). At the same SOC point 211, the SOC of the battery in the scenario of the voltage discharge waveform 203 results in the SOC value being calculated as (4.8-3.4)/4.8=29.2% SOC.

As can be understood, a mis-reporting or wrongful determination of the SOC value of the battery being at 34.6% (e.g., such as by always using the same empty level 202 capacity value without taking the conditions affecting battery energy supply into account) under the scenario presented by the lower waveform 203 presents a higher SOC value than what actually remains in the battery. Accordingly, events such as the battery running out of suppliable energy sooner than expected can occur. To reduce or minimize such errors in determining the remaining SOC in a battery, the residual SOC 204 is calculated and used in the SOC calculations to take the variable empty charge capacity level (e.g., empty charge capacity level 214) into account.

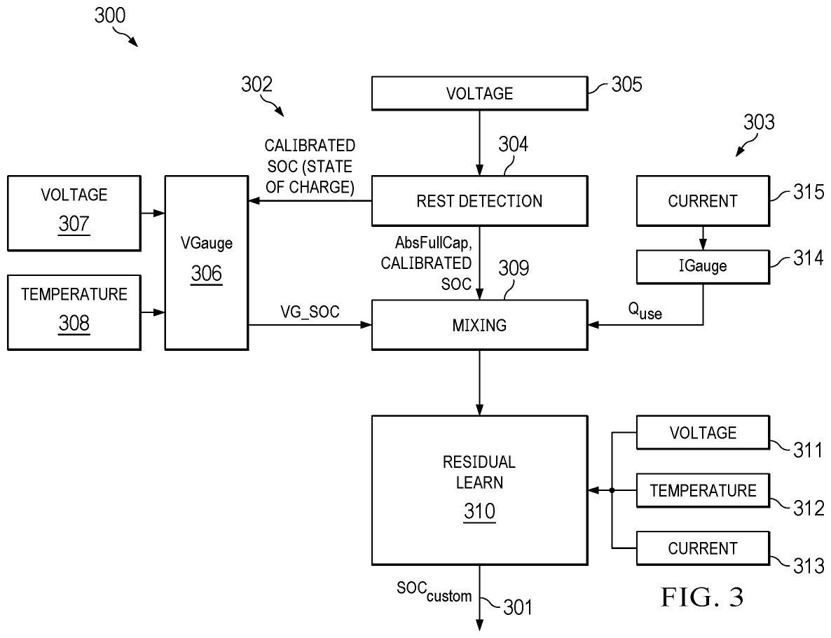

FIG. 3 is a schematic block diagram illustrating a method 300 for determining battery state of charge in an embodiment. In one embodiment, the method 300 may be implemented via a processing system including a processor or controller (e.g., controller 103) that executes processes configured to perform the functions described herein. Implementation of the method 300 generates a custom SOC 301 based on a measured voltage path 302 or an accumulated current path 303. The measured voltage path 302 is useful at the beginning of battery-powered system operation until sufficient current measurement can be accumulated to thereafter use the accumulated current path 303. The measured voltage path 302 includes detecting a rest period at rest detection module 304. During a rest period, a voltage input 305 receives measured voltage from the battery, and a calibrated SOC and an absolute full capacity (AbsFullCap) are calculated. The absolute full capacity value represents the design capacity, Qₘₐₓ, of the battery (e.g., indicator 205 of FIG. 2). The calibrated SOC is provided to a VGauge module 306, which includes a voltage input 307 and a temperature input 308 for receiving the measured voltage and a measured temperature of the battery. Based on these inputs, the VGauge module 306 uses a battery model to generate a battery charge. From the battery charge and temperature, a VGauge SOC (VG_SOC) is determined.

The VGauge SOC is provided to a mixing module 309 to calculate an initial nominal SOC (NomSOC). The nominal SOC is based on a sum of a calculated empty SOC and a full SOC of the battery. A residual learn module 310 refines the initial nominal SOC as described hereinbelow to increase accuracy of the determined SOC of the battery. In particular, the residual learn module 310 is helpful to increase accuracy of the calculation of the residual SOC (e.g., residual SOC 204) to improve the empty SOC value upon which the nominal SOC is calculated. The residual learn module 310 includes a voltage input 311, a temperature input 312, and a current input 313 for receiving measured voltage, temperature, and current measurements to use in determining the residual SOC. The improved calculation via the residual learn module 310 generates the custom SOC 301.

In the accumulated current path portion 303 of the method 300, an IGauge module 314 includes a current input 315 for receiving a measured current during battery use. The IGauge module 314 accumulates the measured current to determine a used amount (Qᵤₛₑ) of stored energy from the battery. The used amount is provided to the mixing module 309 to help determine the nominal SOC value of the battery.

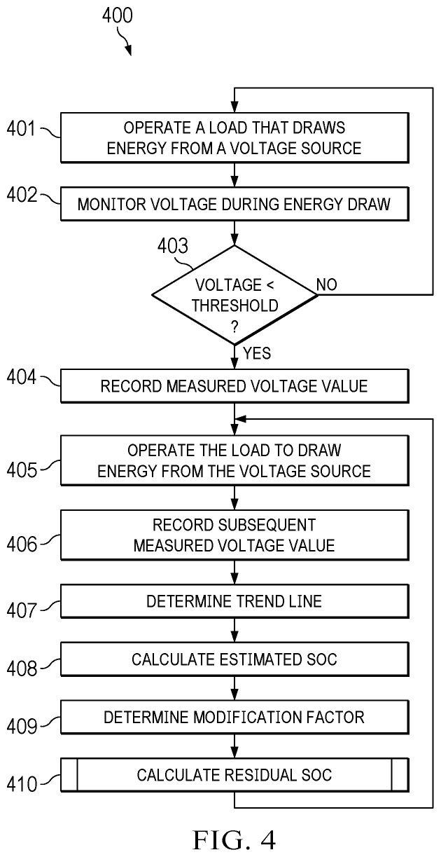

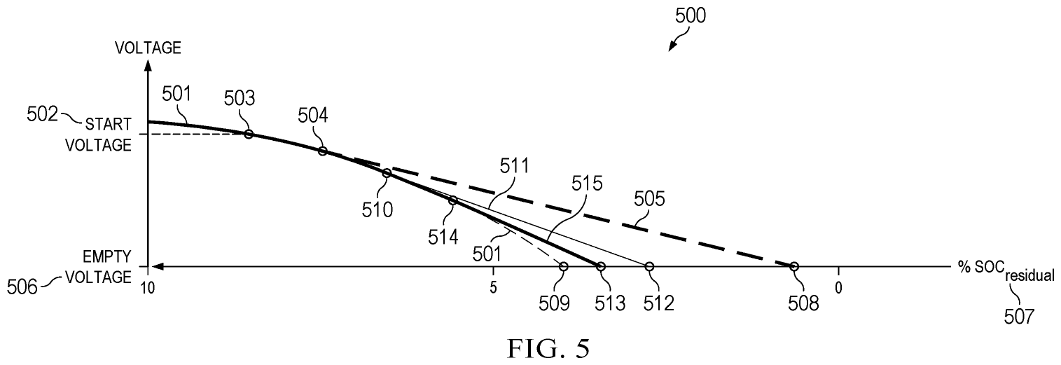

FIG. 4 is a flowchart illustrating a residual SOC method 400 for determining battery residual state of charge in an implementation. In one embodiment, the method 400 may be implemented via a processing system including a processor or controller (e.g., controller 103) that executes processes configured to perform the functions described herein. The residual SOC method 400 may be used in the residual learn module 310 of FIG. 3 in an example. FIG. 5 illustrates a voltage plot 500 visualizing one or more portions of the method 400 of FIG. 4. Referring to FIGS. 4 and 5, method 400 begins at block 401 by operating a load that draws energy from the voltage source such as the battery of which the SOC is to be determined. While the energy is being drawn from the battery, the voltage level 501 of the battery diminishes from an initial level to subsequent, lower levels. The voltage level 501 of the battery is monitored at block 402 during the energy draw from the battery. At block 403, in response to the voltage level 501 being above a predetermined start voltage 502, the method 400 returns to steps 401, 402 to continue operating the load and monitoring the battery voltage level. The start voltage 502 may be determined to be a voltage value near the empty SOC of the battery such as a voltage value adjacent to a sharp dropoff in available SOC that may occur within the last 10% of SOC available. In an example, a voltage value of 3.25 V may be determined to be the start voltage 502 for a voltage discharge waveform such as the voltage discharge waveform 203 of FIG. 2. The start voltage 502 may further vary based on the load conditions on the battery. The controller 103 may, for example, adjust the start voltage 502 taking the accumulated energy usage into account compared with an estimated amount of usable remaining energy. Temperature, age, life cycle, and other operational parameters discussed herein may also influence the adjustment to the start voltage 502.

At block 403, in response to the voltage level 501 being below the predetermined start voltage 502, a first voltage value 503 is measured and recorded at block 404. For example, the controller 103 of FIG. 1 may acquire voltage measurements in the method 400 via the voltage meter 104. As explained hereinbelow, the method 400 determines a model of the SOC_{estimated} value (e.g., a trend line) based on a pair of voltage measurements. It is beneficial to record the voltage measurements at different voltage values of the voltage level 501. Accordingly, the method 400 includes operation of the load to draw further energy from the battery at block 405. A second voltage value 504 is measured and recorded at block 406.

Based on the recorded first and second voltage values 503, 504, a trend line 505 is determined at block 407. As illustrated in FIG. 5, the trend line 505 has a negative slope that intersects with an empty voltage value 506 along a horizontal SOC_{residual} percentage axis 507 of the voltage plot 500. In an example, the empty voltage value 506 corresponds with the empty level 202 illustrated in and discussed with respect to FIG. 2 above. At the intersection, an estimated residual state of charge (SOC_{estimated}) value 508 is determined at block 408.

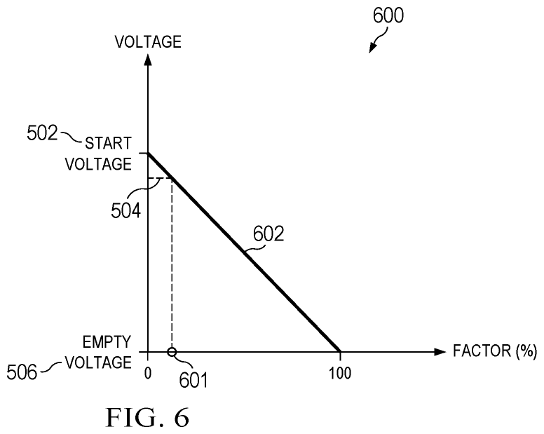

As shown in FIG. 5, the SOC_{estimated} value 508 does not correspond with the actual SOC_{residual} value 509 at the intersection of the voltage level 501 with the SOC_{residual} percentage axis 507. Accordingly, at block 409, a modification factor (Factor) is determined. Referring to FIG. 6, a plot 600 useful for determining the factor is illustrated. Determining the modification factor includes calculating a percentage factor value 601 based on an intersection of a voltage value with a plot line 602. As illustrated, the voltage value corresponds with the later-measured voltage value (e.g., the second voltage value 504) of the pair of voltage values used in creating the trend line 505. For example, in subsequent iterations of the method 400 for determining additional trend lines as described below, the most recent measured voltage value is used to find the intersection with the plot line 602.

Alternatively, the percentage factor value 601 may determined via evaluation of the formula:

$$Factor = 1 - \frac{( measured voltage value - empty voltage value )}{( start voltage value - empty voltage value )} \qquad Eqn . ( 1 )$$

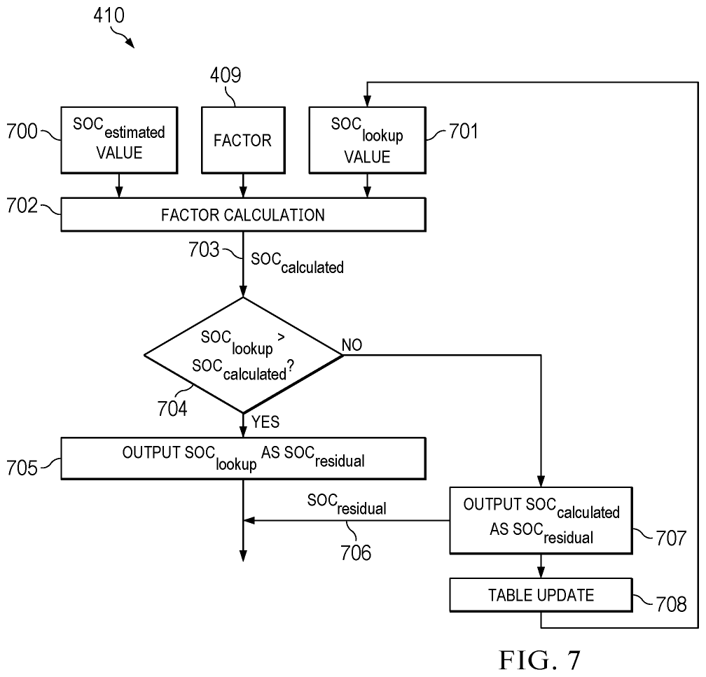

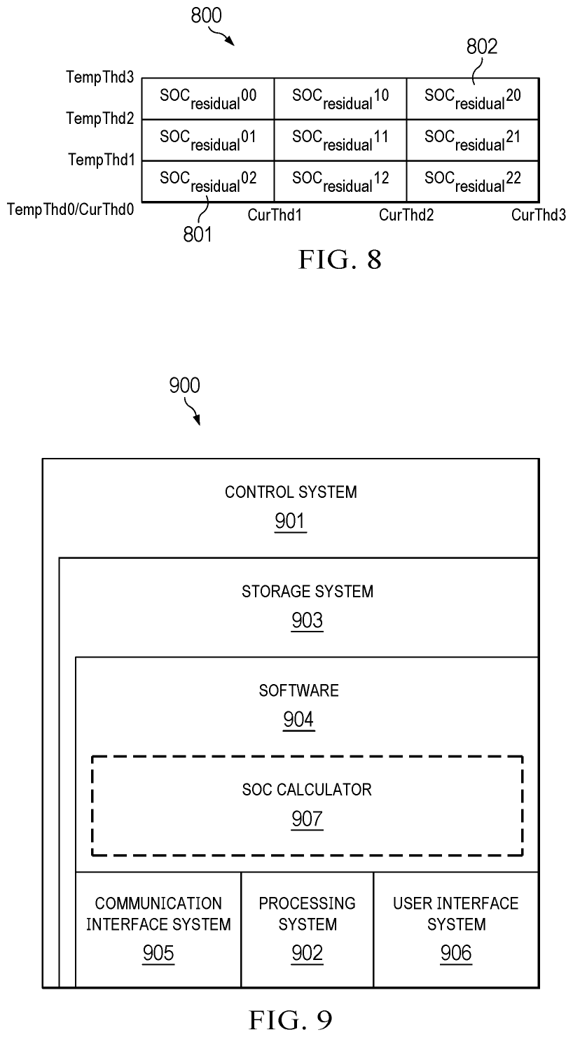

Returning again to FIG. 4, a process 410 for calculating the residual SOC (SOC_{residual}) value is performed to estimate the actual SOC_{residual} value of the battery. FIG. 7 illustrates a flowchart for performing steps of the SOC_{residual} value calculation process 410 according to an embodiment. Block 700 represents the SOC_{estimated} value 508 previously calculated at block 408 of method 400. At block 701, a residual state of charge (SOCₗₒₒₖᵤₚ) value is obtained from a lookup table location of a lookup table (FIG. 8) based on a current value and a temperature value such as from temperature and current inputs 312, 313 of FIG. 3.

FIG. 8 illustrates a lookup table 800 having mapped residual state of charge (SOC_{residual}) in locations of the lookup table 800 based on temperature and current thresholds. The SOC_{residual} values represent expected values for the actual SOC_{residual} value 509 at the various levels of temperature and current and are obtained at block 701 as SOCₗₒₒₖᵤₚ values. Rows in the lookup table 800 represent SOC_{residual} values at respective same temperature threshold values (e.g., TempThd1, TempThd2, TempThd3, etc) among various current threshold values (e.g., CurThd1, CurThd2, CurThd3, etc). Columns in the lookup table 800 represent SOC_{residual} values (e.g., 801, 802) based on respective same current threshold values among various temperature threshold values. The SOC_{residual} values in the lookup table 800 may increase or decrease in threshold values as the positions vary along the rows and columns. may initially start at values of 0% in one example. In another example, the SOC_{residual} values may be initially populated based on expected values. Selected values in the lookup table 800 may be chosen based on a closest threshold value scheme where the values closest to measured temperature and current thresholds are used, an interpolation scheme where the values between threshold are interpolated as needed based on the measured temperature and current thresholds, or other scheme as desired. As described below, the SOC_{residual} values are updated as part of the SOC_{residual} value calculation process 410.

Returning to FIG. 7, the obtained SOC_{estimated} and SOCₗₒₒₖᵤₚ values (blocks 700, 701) are provided to factor calculation block 702 together with the modification factor determined via block 409 of FIG. 4. The factor calculation block 702 generates a SOC_{calculated} value 703 based on the factor, the SOC_{estimated} value, and the SOCₗₒₒₖᵤₚ value. In one example, the SOC_{calculated} value 703 is calculated based on the formula:

$${SOC}_{calculated} = {SOC}_{lookup} \times Factor + {SOC}_{estimated} \times ( 1 - Factor ) \qquad Eqn . ( 2 )$$

As illustrated in Eqn. 2, both of the SOCₗₒₒₖᵤₚ and SOC_{estimated} values are modified based on the factor and summed together to generate the SOC_{calculated} value 703.

At block 704, the SOC_{calculated} and SOCₗₒₒₖᵤₚ values are compared. If the SOCₗₒₒₖᵤₚ value is greater than the SOC_{calculated} value, the SOCₗₒₒₖᵤₚ value is deemed the correct value to use, and at block 705, the SOCₗₒₒₖᵤₚ value is output as the residual SOC value (SOC_{residual}) 706. However, if at block 704 the SOC_{calculated} value is greater than the SOCₗₒₒₖᵤₚ value, the SOC_{calculated} value is deemed the correct value to use, and at block 707, and the SOC_{calculated} value is output as the residual SoC value 706. In addition, as shown in FIG. 7, the SOC_{calculated} value 703 is provided to a table update block 708 that updates the lookup table 800 based on the SOC_{calculated} value 703. Accordingly, the lookup table 800 is updated with the SOC_{calculated} value 703 if the newly SOC_{calculated} value 703 is greater than the value already existing in the lookup table 800 at the location from which the SOCₗₒₒₖᵤₚ value (block 701) was obtained. Updating the lookup table includes substituting or replacing the existing SOCₗₒₒₖᵤₚ value (block 701) with the newly determined SOC_{calculated} value 703. Since the newly SOC_{calculated} value 703 is also the output SOC_{residual} value, updating the lookup table may also be understood to replace the existing SOCₗₒₒₖᵤₚ value (block 701) with the SOC_{residual} value 706.

Returning to FIGS. 4 and 5, after or during calculation of the SOC_{residual} value 703, process control returns to block 405 for iterating blocks 405-410 to calculate a new SOC_{residual} value 703 based on an updated voltage measurement value. For example, after some energy has been drawn from the battery at block 405, a third voltage value 510 is measured and recorded at block 404. Subsequently, a new trend line 511 is determined based on the second voltage value 504 and the third voltage value 510 to identify a new SOC_{estimated} value 512. Thereafter, the SOC_{estimated} value 512 is used in process 410 to update the calculated SOC_{residual} value 703 as described above. As illustrated, a further iteration generates another SOC_{estimated} value 513 based on the third voltage value 510, a fourth voltage value 514, and a generated trend line 515. With each new SOC_{residual} value 703 calculated from SOC_{estimated} values 508, 512, 513, the confidence in the SOC_{residual} value 703 matching the actual SOC_{residual} value 509 increases. Though not illustrated, it is understood that further iterations of the processes described above yield SOC_{estimated} values along the SOC axis 507 closer and closer to the actual SOC_{residual} value 509 in response to the voltage level 501 curving toward the SOC axis 507 as illustrated.

Referring again to FIG. 3, based on the SOC_{residual} values 703 calculated as described herein, a custom state of charge (SOC_{custom}) value 301 is generated by the residual learn module 310 that improves actual SOC capacity of the battery based on remaining SOC and temperature and current values. In one example, the SOC_{custom} value may be determined using the formula:

$${SOC}_{custom} = \frac{{Q}_{max} \times ( 1 - {SOC}_{residual} ) - {Q}_{use}}{{Q}_{max} \times ( 1 - {SOC}_{residual} )} \qquad Eqn . ( 3 )$$

where Qₘₐₓ represents the full chemical capacity of the battery and Qᵤₛₑ represents the amount of used SOC of the battery.

Turning now to FIG. 9, architecture 900 illustrates computing system 901 that is representative of any system or collection of systems in which the various processes, programs, services, and scenarios disclosed herein may be implemented. Examples of computing system 901 include, but are not limited to, general purpose computers, application specific computers such as automotive computers or aerospace computers, embedded computers, industrial computers, server computers, microcontroller units, and personal computers.

Computing system 901 may be implemented as a single apparatus, system, or device or may be implemented in a distributed manner as multiple apparatuses, systems, or devices. Computing system 901 includes, but is not limited to, processing system 902, storage system 903, software 904, communication interface system 905, and user interface system 906 (optional). Processing system 902 is operatively coupled with storage system 903, communication interface system 905, and user interface system 906.

Processing system 902 loads and executes software 904 from storage system 903. Software 904 includes and implements control process 907, which is representative of the processes discussed with respect to the preceding Figures, such as battery SOC methods 300 and 400. When executed by processing system 902, software 904 directs processing system 902 to operate as described herein for at least the various processes, operational scenarios, and sequences discussed in the foregoing implementations. Computing system 901 may optionally include additional devices, features, or functions not discussed for purposes of brevity.

Referring still to FIG. 9, processing system 902 may comprise a microprocessor and other circuitry that retrieves and executes software 904 from storage system 903. Processing system 902 may be implemented within a single processing device but may also be distributed across multiple processing devices or sub-systems that cooperate in executing program instructions. Examples of processing system 902 include one or more general purpose central processing units, graphical processing units, microprocessors, digital signal processors, field-programmable gate arrays, application specific processors, processing circuitry, analog circuitry, digital circuitry, and logic devices, as well as any other type of processing device, combinations, or variations thereof.

Storage system 903 may comprise any computer readable storage media readable by processing system 902 and capable of storing software 904. Storage system 903 may include volatile and nonvolatile, removable, and non-removable media implemented in any method or technology for storage of information, such as computer readable instructions, data structures, program modules, or other data. Examples of storage media include random access memory, read only memory, magnetic disks, optical disks, flash memory, virtual memory and non-virtual memory, magnetic cassettes, magnetic tape, magnetic disk storage or other magnetic storage devices, or any other suitable storage media. In no case is the computer readable storage media a propagated signal.

In addition to computer readable storage media, in some implementations storage system 903 may also include computer readable communication media over which at least some of software 904 may be communicated internally or externally. Storage system 903 may be implemented as a single storage device but may also be implemented across multiple storage devices or sub-systems co-located or distributed relative to each other. Storage system 903 may comprise additional elements, such as a controller, capable of communicating with processing system 902 or possibly other systems.

Software 904 (including process 907) may be implemented in program instructions and among other functions may, when executed by processing system 902, direct processing system 902 to operate as described with respect to the various operational scenarios, sequences, and processes illustrated herein. For example, software 904 may include program instructions for implementing the processes as described herein.

In particular, the program instructions may include various components or modules that cooperate or otherwise interact to carry out the various processes and operational scenarios described herein. The various components or modules may be embodied in compiled or interpreted instructions, or in some other variation or combination of instructions. The various components or modules may be executed in a synchronous or asynchronous manner, serially or in parallel, in a single threaded environment or multi-threaded, or in accordance with any other suitable execution paradigm, variation, or combination thereof. Software 904 may include additional processes, programs, or components, such as operating system software, virtualization software, or other application software. Software 904 may also comprise firmware or some other form of machine-readable processing instructions executable by processing system 902.

In general, software 904 may, when loaded into processing system 902 and executed, transform a suitable apparatus, system, or device (of which computing system 901 is representative) overall from a general-purpose computing system into a special-purpose computing system customized to support image processing. Indeed, encoding software 904 on storage system 903 may transform the physical structure of storage system 903. The specific transformation of the physical structure may depend on various factors in different implementations of this description. Examples of such factors may include, but are not limited to, the technology used to implement the storage media of storage system 903 and whether the computer-storage media are characterized as primary or secondary, etc.

For example, if the computer readable storage media are implemented as semiconductor-based memory, software 904 may transform the physical state of the semiconductor memory when the program instructions are encoded therein, such as by transforming the state of transistors, capacitors, or other discrete circuit elements constituting the semiconductor memory. A similar transformation may occur with respect to magnetic or optical media. Other transformations of physical media are possible without departing from the scope of the present description, with the foregoing examples provided only to facilitate the present discussion.

Communication interface system 905 may include communication connections and devices that allow for communication with other computing systems (not shown) over communication networks (not shown). Examples of connections and devices that together allow for inter-system communication may include network interface cards, antennas, power amplifiers, RF circuitry, transceivers, and other communication circuitry. The connections and devices may communicate over communication media to exchange communications with other computing systems or networks of systems, such as metal, glass, air, or any other suitable communication media. The aforementioned media, connections, and devices are well known and need not be discussed at length here.

Communication between computing system 901 and other computing systems (not shown), may occur over a communication network or networks and in accordance with various communication protocols, combinations of protocols, or variations thereof. Examples include intranets, internets, the Internet, local area networks, wide area networks, wireless networks, wired networks, virtual networks, software defined networks, data center buses and backplanes, or any other type of network, combination of network, or variation thereof. The aforementioned communication networks and protocols are well known and need not be discussed at length here.

As will be appreciated by one skilled in the art, aspects of the present invention may be embodied as a system, method, or computer program product. Accordingly, aspects of the present invention may take the form of an entirely hardware implementation, an entirely software implementation (including firmware, resident software, micro-code, etc.) or an implementation combining software and hardware aspects that may all generally be referred to herein as a “circuit,” “module” or “system.” Furthermore, aspects of the present invention may take the form of a computer program product embodied in one or more computer readable medium(s) having computer readable program code embodied thereon.

Indeed, the included descriptions and figures depict specific implementations to teach those skilled in the art how to make and use the best mode. For the purpose of teaching inventive principles, some conventional aspects have been simplified or omitted. Those skilled in the art will appreciate variations from these implementations that fall within the scope of the disclosure. Those skilled in the art will also appreciate that the features described above may be combined in various ways to form multiple implementations. As a result, the invention is not limited to the specific implementations described above, but only by the claims and their equivalents.

The above description and associated figures teach the best mode of the invention. The following claims specify the scope of the invention. Note that some aspects of the best mode may not fall within the scope of the invention as specified by the claims. Those skilled in the art will appreciate that the features described above can be combined in various ways to form multiple variations of the invention. Thus, the invention is not limited to the specific embodiments described above, but only by the following claims and their equivalents.

1. A method comprising:
recording a first voltage value of a voltage source;
recording a second voltage value of the voltage source;
determining a first estimated residual state of charge value (SOC_{estimated}) of the voltage source based on the first voltage value and the second voltage value;
determining a factor based on one of the first voltage value and the second voltage value; and
calculating a residual state of charge value (SOC_{residual}) of the voltage source based on the first estimated residual state of charge value (SOC_{estimated}) and based on the factor.

2. The method of claim 1, further comprising:
recording the first voltage value after a state of charge of the voltage source falls to a starting voltage value.

3. The method of claim 1, further comprising:
obtaining a residual state of charge value (SOCₗₒₒₖᵤₚ) from a lookup table location of a lookup table based on a current value and a temperature value.

4. The method of claim 3, wherein calculating the residual state of charge value (SOC_{residual}) comprises:
determining a calculated state of charge value (SOC_{calculated}) based on:
modifying the residual state of charge value (SOCₗₒₒₖᵤₚ) based on the factor; and
modifying the first estimated residual state of charge value (SOC_{estimated}) based on the factor.

5. The method of claim 4, wherein determining the calculated state of charge value (SOC_{calculated}) comprises:
determining the calculated state of charge value (SOC_{calculated}) based on a formula:
$${SOC}_{calculated} = {SOC}_{lookup} \times Factor + {SOC}_{estimated} \times ( 1 - Factor ) .$$

6. The method of claim 4, wherein calculating the residual state of charge value (SOC_{residual}) comprises:
using the residual state of charge value (SOCₗₒₒₖᵤₚ) as the residual state of charge value (SOC_{residual}) based on the residual state of charge value (SOCₗₒₒₖᵤₚ) being greater than the calculated state of charge value (SOC_{calculated}); and
using the calculated state of charge value (SOC_{calculated}) as the residual state of charge value (SOC_{residual}) based on the residual state of charge value (SOCₗₒₒₖᵤₚ) being less than the calculated state of charge value (SOC_{calculated}).

7. The method of claim 6, further comprising:
updating the lookup table with the calculated state of charge value (SOC_{calculated}) based on the residual state of charge value (SOCₗₒₒₖᵤₚ) being less than the calculated state of charge value (SOC_{calculated}).

8. The method of claim 1, wherein determining the factor comprises:
determining a percentage value based on a value of the first estimated residual state of charge value (SOC_{estimated}) compared with a range between a starting voltage value and an empty voltage value.

9. The method of claim 1, further comprising:
recording a third voltage value of the voltage source;
determining a second estimated residual state of charge value based on the second voltage value and the third voltage value;
updating the factor based on one of the second voltage value and the third voltage value; and
updating the residual state of charge value (SOC_{residual}) based on the second estimated residual state of charge value and based on the updated factor.

10. The method of claim 1, further comprising:
causing a load to drain energy from the voltage source between recording the first and second voltage values.

11. An apparatus, comprising:
a controller configured to:
receive a first voltage measurement value of a DC voltage source from a voltage sensor;
receive a second voltage measurement value of the DC voltage source from the voltage sensor;
calculate an estimated residual state of charge value (SOC_{estimated}) based on the first and second voltage measurement values;
calculate a modification factor (Factor); and
calculate a residual state of charge (SOC_{residual}) of the DC voltage source based on the estimated residual state of charge value (SOC_{estimated}) and on the modification factor (Factor).

12. The apparatus of claim 11, wherein the controller is further configured to calculate the residual state of charge (SOC_{residual}) of the DC voltage source further based on a residual state of charge value (SOCₗₒₒₖᵤₚ).

13. The apparatus of claim 12, wherein the controller is further configured to calculate the residual state of charge (SOC_{residual}) of the DC voltage source further based on a formula:
$${SOC}_{calculated} = {SOC}_{lookup} \times Factor + {SOC}_{estimated} \times ( 1 - Factor ) .$$

14. The apparatus of claim 12, wherein the controller is further configured to acquire the residual state of charge value (SOCₗₒₒₖᵤₚ) from a lookup table based on a temperature and based on an amount of current draw from the DC voltage source.

15. The apparatus of claim 11, wherein the DC voltage source comprises a battery.

16. An apparatus, comprising:
one or more computer readable storage media;
program instructions stored on the one or more computer readable storage media, the program instructions executable by a processing system to direct the processing system to:
receive a voltage measurement and a subsequent voltage measurement of a voltage source;
estimate a residual state of charge value (SOC_{estimated}) based on the voltage measurement and the subsequent voltage measurement;
determine a factor; and
determine a residual state of charge (SOC_{residual}) of the voltage source based on the estimated residual state of charge value and based on the factor.

17. The apparatus of claim 16, wherein the program instructions further direct the processing system to:
determine a trend line based on the voltage measurement and the subsequent voltage measurement; and
wherein the program instructions that direct the processing system to estimate the residual state of charge value (SOC_{estimated}) further direct the processing system to:
determine an intersection of the trend line and an axis line representing an empty state of charge of the voltage source.

18. The apparatus of claim 16, wherein the program instructions that direct the processing system to determine the factor further direct the processing system to:
determine the factor based on the subsequent voltage measurement.

19. The apparatus of claim 16, wherein the program instructions further direct the processing system to:
obtain a stored residual state of charge value (SOCₗₒₒₖᵤₚ) from a lookup table based on a current draw from the voltage source by a load and based on a temperature of the voltage source.

20. The apparatus of claim 19, wherein the program instructions further direct the processing system to:
replace the stored residual state of charge value (SOCₗₒₒₖᵤₚ) with the determined residual state of charge (SOC_{residual}) based on the determined residual state of charge (SOC_{residual}) being greater than the stored residual state of charge value (SOCₗₒₒₖᵤₚ).
